(19) United States
(12) Patent Application Publication
(10) Pub. No.: US 2012/0315468 A1
(43) Pub. Date: Dec. 13, 2012

(54) COATED ARTICLE AND METHOD FOR MAKING SAME

(75) Inventors: HUANN-WU CHIANG, Tu-Cheng (TW); CHENG-SHI CHEN, Tu-Cheng (TW); CONG LI, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD, Shenzhen City (CN)

(21) Appl. No.: 13/238,160

(22) Filed: Sep. 21, 2011

(30) Foreign Application Priority Data
Jun. 13, 2011 (CN) 201110157304.5

(51) Int. Cl. B32B 15/04; C23C 14/34; C23C 16/44; B32B 18/00; C23C 16/40

(52) U.S. Cl. 428/336; 428/448; 428/702; 428/469; 428/450; 427/255.33; 427/255.34; 204/192.15

(57) ABSTRACT

A coated article is provided. A coated article includes a substrate, a ceramic layer deposited on the substrate by vacuum plating, and a color layer deposited on the ceramic layer. The ceramic layer substantially includes substance M, elemental O and elemental N, wherein the M is Al or Si. The color layer substantially includes metal M′, elemental O and elemental N, wherein the M′ is Al or Zn.

### CROSS-REFERENCE TO RELATED APPLICATIONS

This application is one of the six related co-pending U.S. patent applications listed below. All listed applications have the same assignee. The disclosure of each of the listed applications is incorporated by reference into the other listed applications.

| Attorney | | |
|---|---|---|
| Docket No. | Title | Inventors |
| US 40037 | COATED ARTICLE AND METHOD | HUANN-WU |
| | FOR MAKING SAME | CHIANG et al. |
| US 40225 | COATED ARTICLE AND METHOD | HUANN-WU |
| | FOR MAKING SAME | CHIANG et al. |
| US 40740 | COATED ARTICLE AND METHOD | HSIN-PEI |
| | FOR MAKING SAME | CHANG et al. |
| US 40741 | COATED ARTICLE AND METHOD | WEN-RONG |
| | FOR MAKING SAME | CHEN et al. |
| US 40742 | COATED ARTICLE AND METHOD | HSIN-PEI |
| | FOR MAKING SAME | CHANG et al. |
| US 40968 | COATED ARTICLE AND METHOD | WEN-RONG |
| | FOR MAKING SAME | CHEN et al. |

### BACKGROUND

1. Technical Field

The exemplary disclosure generally relates to coated articles and a method for manufacturing the coated articles, particularly coated articles having a bone china appearance and a method for making the coated articles.

2. Description of Related Art

Vacuum deposition, anodic treatment and spray painting are used to form a thin film or coating on housings of portable electronic devices, to improve appearance of housings. The housings may be presented with a colorful appearance, but cannot present a high level of whiteness, brightness, and translucency appearance like a bone china.

The traditional formulation for the bone china contains about 25% kaolin, 25% Cornish stone and 50% bone ash. The bone ash for the bone china may be made from cattle bones having a lower amount of iron. The expensive cattle bones, the complex manufacturing process and the low yielding efficiency make bone china very expensive and thus not economically feasible in the construction of housings of portable electronic devices.

Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the exemplary coated article and method for manufacturing the coated article. Moreover, in the drawings like reference numerals designate corresponding parts throughout the several views. Wherever possible, the same reference numbers are used throughout the drawings to refer to the same or like elements of an embodiment.

FIG. 1 is a cross-section view of an exemplary embodiment of coated article.

FIG. 2 is a schematic view of a vacuum sputtering coating machine for manufacturing the coated article of FIG. 1.

### DETAILED DESCRIPTION

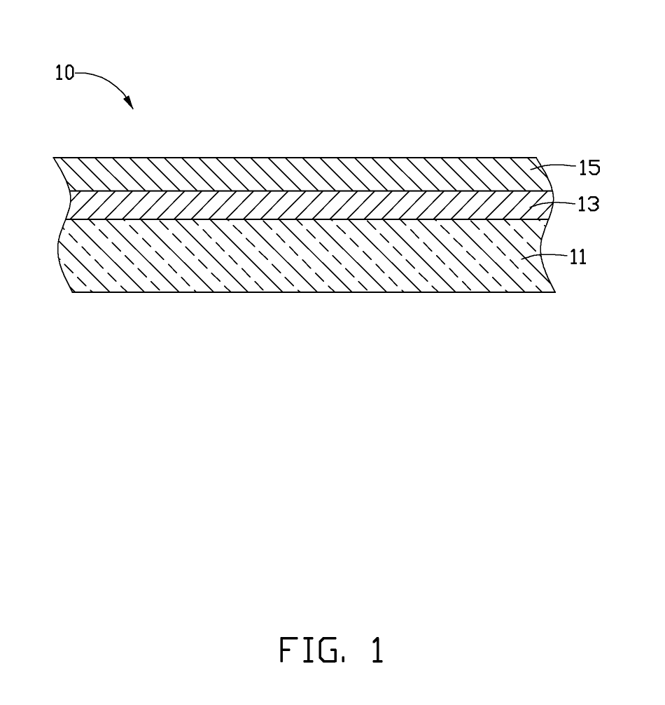

FIG. 1 shows an exemplary embodiment of a coated article. The coated article 10 includes a substrate 11, a ceramic layer 13 formed on the substrate 11 and a color layer 15 formed on the ceramic layer 13. The coated article 10 may be a housing of a mobile phone, personal digital apparatus (PDA), note book computer, MP3, MP4, GPS navigator, or digital camera.

The substrate 11 may be made of metal, such as stainless steel, aluminum, aluminum alloy, magnesium and magnesium alloy. The substrate 11 may instead be made of nonmetal material, such as plastic.

The ceramic layer 13 substantially includes substance M, elemental oxygen (O) and elemental nitrogen (N), wherein M is metal or non-metal, such as elemental aluminum (Al) or elemental silicon (Si). When M is Al, the ceramic layer 13 substantially includes Al₂O₃ and N in solid solution, wherein the mass percentage of elemental Al is about 35-42%, the mass percentage of elemental O is about 50-55% and the mass percentage of elemental N is about 3-15%. When M is Si, the ceramic layer 13 substantially includes SiO₂ and N in solid solution, wherein the mass percentage of elemental Si is about 30-40%, the mass percentage of elemental O is about 50-55% and the mass percentage of elemental N is about 5-20%.

The ceramic layer 13 may be presented with a transparent glass-like appearance. The ceramic layer 13 is deposited by magnetron sputtering, vacuum evaporation or arc ion plating. The ceramic layer 13 has a thickness of about 1 μm to about 2 μm.

The color layer 15 may be deposited by physical vapor deposition methods such as magnetron sputtering, vacuum evaporation or arc ion plating. The color layer 15 substantially includes substance M′, elemental O and elemental N, wherein the M′ is metal, such as elemental aluminum (Al) or elemental zinc (Zn). When M′ is elemental Al, the color layer 15 substantially includes Al₂O₃, simple substance Al and N in solid solution. When the M′ is elemental Zn, the color layer 15 substantially includes ZnO₂, simple substance Zn and N in solid solution. In the color layer 15, the mass percentage of substance M′ is about 80-90%, the mass percentage of elemental O is about 5-9% and the mass percentage of elemental N is about 1-15%.

The 60 degree specula gloss (Gs 60°) of the color layer 15 is about 90-106. The color layer 15 has an L* value between about 90 to about 95, an a* value between about −0.5 to about 0.5, and a b* value between about −0.5 to about 0.5 in the CIE L*a*b* (CIE LAB) color space, so the color layer 15 is white.

The ceramic layer 13 combined with the color layer 15 cause the coated article 10 to present a high level of whiteness, brightness and translucency appearance like bone china.

A method for manufacturing the coated article 10 may include at least the following steps:

Providing a substrate 11. The substrate 11 may be made of metal, such as stain steel, aluminum, aluminum alloy, magnesium and magnesium alloy. The substrate 11 may instead be made of non-metal material, such as plastic.

Pretreating the substrate 11 by washing with a solution (e.g., Alcohol or Acetone) in an ultrasonic cleaner to remove contaminations, such as grease, or dirt. The substrate 11 is then dried.

The substrate 11 is then cleaned by argon plasma cleaning.

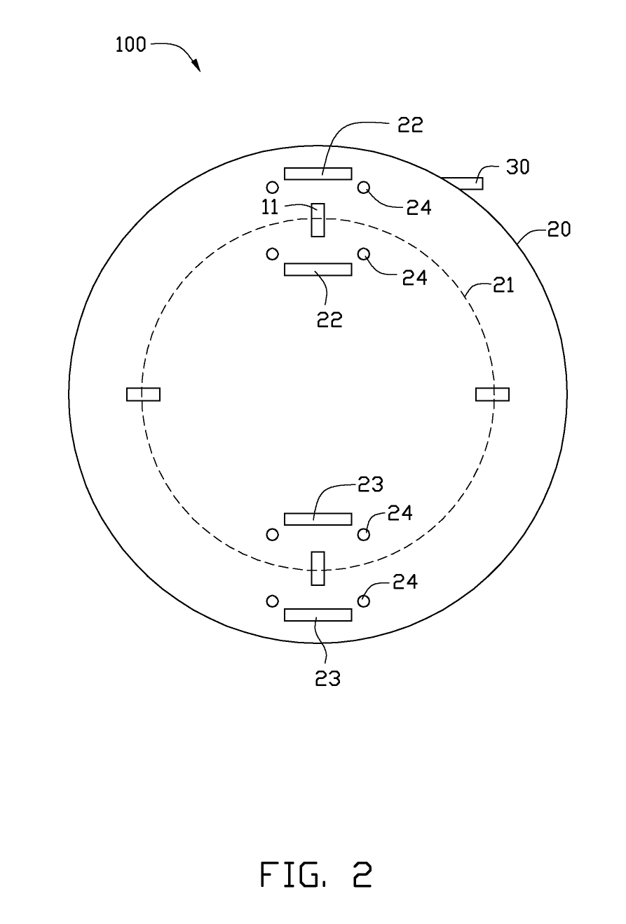

Providing a vacuum sputtering coating machine 100. Referring to FIG. 2, the vacuum sputtering coating machine 100 includes a sputtering coating chamber 20 and a vacuum pump 30 connected to the sputtering coating chamber 20. The vacuum pump 30 is used to evacuate the sputtering coating chamber 20. The vacuum sputtering coating machine 100 further includes a rotating bracket 21, two first targets 22, two second targets 23, and a plurality of gas inlets 24. The rotating bracket 21 rotates the substrate 11 in the sputtering coating chamber 20 relative to the first targets 22 and the second targets 23. The two first targets 22 face to each other, and are located on opposite sides of the rotating bracket 21, and the same arrangement applied to the two second targets 23. In this exemplary embodiment, the first targets 22 are made of Al, Al alloy, Si or Si alloy, the second targets 23 are made of Al, Al alloy, Zn or Zn alloy. When the first targets 22 are made of Al alloy or Si alloy, the mass percent of the elemental Al or elemental Si is about 85-90%. When the second targets 23 are made of Al alloy or Zn alloy, the mass percent of the elemental Al or elemental Zn is about 85-90%.

Cleaning the substrate 11 by argon (Ar) plasma. The substrate 11 is retained on a rotating bracket 21 in a sputtering coating chamber 20. The vacuum level inside the sputtering coating chamber 20 is set to about 8.0*10⁻³ Pa. Argon gas is fed into the sputtering coating chamber 20 at a flux rate about 100 Standard Cubic Centimeters per Minute (sccm) to about 400 sccm from the gas inlets 24. A bias voltage applied to the substrate 11 may be between about −200 volts (V) and about −500 volts. The argon particles strike against and clean the surface. Plasma cleaning the substrate 11 may take from about 3 min to about 20 min.

A ceramic layer 13 is deposited on the substrate 11. The temperature in the sputtering coating chamber 20 is set between about 20° C. (Celsius degree) and about 200° C. Argon may be used as a working gas and is injected into the sputtering coating chamber 20 at a flow rate from about 100 sccm to about 300 sccm. Nitrogen (N₂) and oxygen (O₂) may be used as reaction gases. The nitrogen may have a flow rate of about 80 sccm to about 300 sccm, the oxygen may have a flow rate of about 50 sccm to about 200 sccm. The first targets 22 in the sputtering coating chamber 20 are evaporated at a power between about 5 kW and about 10 kW. A bias voltage applied to the substrate 11 may be between about −100 volts and about −300 volts, for between about 10 minutes and about 30 minutes, to deposit the ceramic layer 13 on the substrate 11. The ceramic layer 13 has a thickness of about 1 μm to about 2 μm.

Depositing the color layer 15 on the ceramic layer 13. The internal temperature of the sputtering coating chamber 20 is maintained at about 20° C. to about 200° C. Argon may be used as a working gas and is injected into the sputtering coating chamber 20 at a flow rate from about 100 sccm to about 300 sccm. Nitrogen (N₂) and oxygen (O₂) may be used as reaction gases. The nitrogen may have a flow rate of about 80 sccm to about 300 sccm, the oxygen may have a flow rate of about 50 sccm to about 200 sccm. The second targets 23 in the sputtering coating chamber 20 are evaporated at a power between about 5 kW to about 10 kW. The substrate 11 may have a negative bias voltage about −100 V to about −300 V to deposit the color layer 15 on the ceramic layer 13. Depositing of the color layer 15 may take from about 3 min to about 20 min.

It is to be understood that the method for manufacturing the coated article 10 may further includes depositing a prime layer between the substrate 11 and the ceramic layer 13 to improve bonding force between the substrate 11 and the ceramic layer 13 so the ceramic layer 13 can be firmly deposited on the substrate 30. The prime layer may be Al alloy layer or Si alloy layer.

It is to be understood that the method for manufacturing the coated article 10 may further includes depositing a bonding layer between the ceramic layer 13 and the color layer 15 to improve bonding force between the ceramic layer 13 and the color layer 15. Therefore, the color layer 15 can be firmly formed on the ceramic layer 13. The bonding layer may be Al layer, Al alloy layer, Zn layer or Zn alloy layer.

The coated article 10 manufactured by the method present a bone china appearance. The method of the coated article 10 is simpler, can be produced at further higher productivity and lower cost relative to the method of the typical bone china products. The coated article 10 may be widely used in many fields (e.g., electronic products, automobiles and houseware articles) as the coated article 10 can be mass production on an industrial scale. Additionally, the substrate 11 can be made of stainless steel, Al, Al alloy, Mg, Mg alloy or plastic can improve the toughness of the coated article 10. Thus, the improvement in toughness of the coated article 10 can cause the coated article 10 to have outstanding anti-fragility properties. Furthermore, when the substrate 11 is made of light metal (e.g., Al, Al alloy, Mg and Mg alloy) or plastic can cause the coated article 10 more lightly relative to the typical bone china products.

It is to be understood, however, that even through numerous characteristics and advantages of the exemplary disclosure have been set forth in the foregoing description, together with details of the system and function of the disclosure, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A coated article, comprising:
a substrate;
a ceramic layer deposited on the substrate, the ceramic layer substantially including substance M, elemental O and elemental N, wherein M is elemental Al or elemental Si; and
a color layer deposited on the ceramic layer, the color layer substantially including metal M′, elemental O and elemental N, wherein M′ is elemental Al or elemental Zn.

2. The coated article as claimed in claim 1, wherein when M is Al, the ceramic layer substantially includes Al₂O₃ and N in solid solution.

3. The coated article as claimed in claim 2, wherein the mass percentage of elemental Al is about 35-42%, the mass percentage of elemental O is about 50-55% and the mass percentage of elemental N is about 3-15%.

4. The coated article as claimed in claim 1, wherein M is Si, the ceramic layer substantially includes SiO₂ and N in solid solution.

5. The coated article as claimed in claim 4, wherein the mass percentage of elemental Si is about 30-40%, the mass percentage of elemental O is about 50-55% and the mass percentage of elemental N is about 5-20%.

6. The coated article as claimed in claim 1, wherein the M′ is Al, the color layer is substantially includes Al₂O₃, simple substance Al and N in solid solution.

7. The coated article as claimed in claim 6, wherein the mass percentage of elemental Al is about 80-90%, the mass percentage of elemental O is about 5-9% and the mass percentage of elemental N is about 1-15%.

8. The coated article as claimed in claim 1, wherein the M′ is Zn, the color layer is substantially includes ZnO₂, simple substance Zn and N in solid solution.

9. The coated article as claimed in claim 8, wherein the mass percentage of elemental Si is about 80-90%, the mass percentage of elemental O is about 5-9% and the mass percentage of elemental N is about 1-15%.

10. The coated article as claimed in claim 1, wherein the ceramic layer has a thickness of about 1 μm to about 2 μm.

11. The coated article as claimed in claim 1, wherein the 60 degree specular gloss of the color layer is about 90-106.

12. The coated article as claimed in claim 1, wherein the color layer has an L* value between about 90 to about 95, an a* value between about −0.5 to about 0.5, and a b* value between about −0.5 to about 0.5 in the CIE L*a*b* color space.

13. The coated article as claimed in claim 1, wherein the substrate is made of material selected from one of stainless steel, aluminum, aluminum alloy, magnesium, magnesium alloy and plastic.

14. A method for manufacturing an article comprising:
providing a substrate;
depositing a ceramic layer, the ceramic layer substantially including substance M, elemental O and elemental N, wherein the M is Al or Si, during deposition of the ceramic layer, N₂ and O₂ used as reaction gases, the first targets are made of Al, Al alloy, Si or Si alloy; and
depositing a color layer, the color layer substantially including substance M′, elemental O and elemental N, wherein the M′ is Al or Zn, during deposition of the ceramic layer, N₂ and O₂ used as reaction gases, the second targets are made of Al, Al alloy, Zn or Zn alloy.

15. The method of claim 14, wherein during deposition of the ceramic layer on the substrate, the substrate is retained in a sputtering coating chamber of a vacuum sputtering coating machine; the temperature in the sputtering coating chamber is set between about 20° C. and about 200° C.; argon is fed into the sputtering coating chamber at a flux between about 100 sccm and about 300 sccm, nitrogen is fed into the sputtering coating chamber at a flux between about 80 sccm and 300 sccm and oxygen is fed into the sputtering coating chamber at a flux between about 50 sccm and 200 sccm; the first targets in the sputtering coating chamber are evaporated at a power between about 5 kW and about 10 kW; a bias voltage applied to the substrate is between about −100 volts and about −300 volts for between about 10 minutes and about 30 minutes, to deposit the ceramic layer on the substrate.

16. The method of claim 15, wherein when the first targets are made of Al alloy, the mass percent of the elemental Al is about 85-90%, when the first targets are made of Si alloy, the mass percent of the elemental Si is about 85-90%.

17. The method of claim 14, wherein during deposition of the color layer on the ceramic layer, the substrate is retained in a sputtering coating chamber of a vacuum sputtering coating machine; the temperature in the sputtering coating chamber is set between about 20° C. and about 200 V; argon is fed into the sputtering coating chamber at a flux between about 100 sccm and about 300 sccm, nitrogen is fed into the sputtering coating chamber at a flux between about 80 sccm and 300 sccm and oxygen is fed into the sputtering coating chamber at a flux between about 50 sccm and 200 sccm; the second targets in the sputtering coating chamber are evaporated at a power between about 5 kW and about 10 kW; a bias voltage applied to the substrate is between about −100 volts and about −300 volts for between about 3 minutes and about 20 minutes, to deposit the color layer on the ceramic layer.

18. The method of claim 17, wherein when the second targets are made of Al alloy, the mass percent of the elemental Al is about 85-90%, when the first targets are made of Zn alloy, the mass percent of the elemental Zn is about 85-90%.
